(19) United States
(12) Patent Application Publication
(10) Pub. No.: US 2021/0057673 A1
(43) Pub. Date: Feb. 25, 2021

(54) DISPLAY MODULE AND FULL LAMINATION METHOD THEREOF

(71) Applicant: Wuhan China Star Optoelectronics Technology Co., Ltd., Wuhan, Hubei (CN)

(72) Inventors: Pengfei YU, Wuhan, Hubei (CN); Tao SONG, Wuhan, Hubei (CN); Guipeng TU, Wuhan, Hubei (CN)

(21) Appl. No.: 16/623,563

(22) PCT Filed: Nov. 5, 2019
(86) PCT No.: PCT/CN2019/115723

§ 371 Date: Dec. 17, 2019

(30) Foreign Application Priority Data
Aug. 22, 2019 (CN) 20190779416.0

(51) Int. Cl. H01L 51/52; H01L 27/32; H01L 51/00; H01L 51/56; G02F 1/1335; G02F 1/1333; B32B 7/12; B32B 17/10; B32B 3/26; B32B 37/12; B32B 37/10; G06F 3/041; G06K 9/00; C09J 4/00; C09J 5/00

(52) U.S. Cl. CPC H01L 51/5246; C09J 2301/416; H01L 27/3234; H01L 27/3244; H01L 51/0024; H01L 51/5281; H01L 51/5284; H01L 51/56; G02F 1/133512; G02F 1/13338; G02F 1/133528; B32B 7/12; B32B 17/10458; B32B 17/10972; B32B 3/266; B32B 17/1099; B32B 37/12; B32B 37/1009; G06F 3/041; G06K 9/0004; C09J 4/00; C09J 5/00; G02F 2001/133302; G02F 2202/28; B32B 2037/1253; B32B 2457/208; B32B 2307/412; B32B 2307/42; H01L 27/323

(57) ABSTRACT

The present invention provides a display module and a full lamination method. The display module includes a cover plate, a glass substrate, a display panel, and an adhesive layer. The adhesive layer includes a main part and an extension part. The adhesive layer is extended beyond the glass substrate, and UV irradiation is performed on a lateral side of the display module to solidify the extension part, so that impurities such as ambient water/moisture are prevented from entering the inside of the display module. Two deaerating treatments are performed to effectively avoid occurrence of bubbles at a boundary between a visible region and a black matrix region.

### FIELD OF THE DISCLOSURE

The present invention relates to a field of display devices and in particular, to a display module and a full lamination method thereof.

### DESCRIPTION OF THE RELATED ART

Full lamination refers to a process of fully integrating a touch screen and a display in touch display industries. The full lamination method can make the screen look more transparent, enhance display performance, and protect the screen from foreign objects.

The display module has a cover plate and a display panel completely attached to each other. The cover plate includes a visible region (VA) and a black matrix (BM) region. A blind-hole product refers to a product having an opening in a polarizer. Because requirements for deaerating a blind-hole region and an in-plane region are not the same, it is unable to remove all bubbles in the blind-hole product by only one deaerating treatment. Moreover, in a full-lamination manufacturing process, an adhesive is usually cured after the blind-hole product undergoes one deaerating treatment. However, because the adhesive in the black matrix region is shielded, the adhesive is unable to be cured in time. Therefore, it is easy to produce a certain amount of bubbles at a boundary between the visual region and the black matrix (BM) region of the cover plate, which affects the product quality. The liquid adhesive tends to overflow from the side, and ambient water/moisture easily enters the inside of the product.

Accordingly, it is required to provide a new display module and a full lamination method thereof to solve the above problems.

### SUMMARY

The present disclosure provides a display module and a full lamination method thereof, which solves the problem that when a cover plate and a display panel of a conventional display module are completely attached to each other, bubbles are easily generated at a boundary between a visible region and a black matrix region of the cover plate, and ambient water/moisture easily enters the inside of the display module from a lateral side.

Accordingly, the present invention provides solutions as follows.

The present invention provides a display module, comprising:

a cover plate comprising a visible region and a black matrix region surrounding the visible region;

a glass substrate combined with the cover plate, wherein an outer edge of the glass substrate is disposed corresponding to the black matrix region, and a touch sensing circuit is disposed on the glass substrate;

a display panel disposed at one side of the glass substrate away from the cover plate; and

an adhesive layer disposed between the glass substrate and the display panel, the adhesive layer comprising a main part and an extension part, wherein the extension part is disposed at a periphery of the main part, wherein an orthographic projection of an outer edge of the extension part, which is projected onto the glass substrate, is located outside the glass substrate.

According to one embodiment of the display module, the orthographic projection of the outer edge of the extension part, which is projected onto the glass substrate, coincides with an outer edge of the black matrix region.

According to one embodiment of the present invention, the display module further comprises a polarizer, wherein the polarizer is disposed on one side of the display panel adjacent to the cover plate, a blind hole is defined in the polarizer, the blind hole is disposed corresponding to the visible region of the cover plate, and the adhesive layer is snugly attached to a sidewall and a bottom of the blind hole.

In the display module according to one embodiment of the present invention, a camera and a fingerprint identification device are disposed in a bottom portion of the display panel and arranged corresponding to the blind hole.

In the display module according to one embodiment of the present invention, the adhesive layer is made of an ultraviolet-curable optically clear adhesive (OCA).

In the display module according to one embodiment of the present invention, the display panel is a liquid crystal display (LCD) panel or an organic light-emitting diode (OLED) display panel.

According to one embodiment of the present invention, the display module is a touch display module.

The present invention provides a display module, comprising:

a cover plate comprising a visible region and a black matrix region surrounding the visible region;

a glass substrate combined with the cover plate, wherein an outer edge of the glass substrate is disposed corresponding to the black matrix region;

a display panel disposed on one side of the glass substrate away from the cover plate;

and

an adhesive layer disposed between the glass substrate and the display panel, the adhesive layer comprising a main part and an extension part, wherein the extension part is disposed at a periphery of the main part, wherein an orthogonal projection of the outer edge of the extension part, which is projected onto the glass substrate, is located at an outer edge of the glass substrate.

In the display module according to one embodiment of the present invention, an orthographic projection of the outer edge of the extension part, which is projected onto the glass substrate, coincides with an outer edge of the black matrix region.

According to one embodiment of the present invention, the display module further comprises a polarizer, wherein the polarizer is disposed on one side of the display panel adjacent to the cover plate, a blind hole is defined in the polarizer, the blind hole is arranged corresponding to the visible region of the cover plate, and the adhesive layer is snugly attached to a sidewall and a bottom of the blind hole.

In the display module according to one embodiment of the present invention, a camera and a fingerprint identification device are disposed in a bottom portion of the display panel and arranged corresponding to the blind hole.

In the display module according to one embodiment of the present invention, the adhesive layer is an ultraviolet (UV)-curable optically clear adhesive (OCA).

In the display module according to one embodiment of the present invention, the display panel is a liquid crystal display (LCD) panel or an organic light-emitting diode (OLED) display panel.

In the display module according to one embodiment of the present invention, the display module is a touch display module.

The present invention provides a full lamination method of a display module, comprising following steps:

step S10: aligning and attaching an adhesive layer to a glass substrate in combination with a cover plate in a vacuum environment;

step S20: aligning and attaching the cover plate to a display panel in the vacuum environment;

step S30: performing a first deaerating treatment on the adhesive layer;

step S40: performing ultraviolet (UV) irradiation on a front surface of the display module by using a UV irradiation device to cure a main part of the adhesive layer; and

step S50: performing UV irradiation on a lateral surface of the display module by using the UV light irradiation device to cure an extension part of the adhesive layer.

According to one embodiment of the full lamination method, in step S40, after performing the first deaerating treatment on the adhesive layer, a blind hole defined in a polarizer is shielded by a light shield to cure the main part of the adhesive layer.

According to one embodiment of the full lamination method of the display module, step S50 further comprises performing a second deaerating treatment, and then performing UV irradiation on the lateral surface of the display module by using the UV irradiation device to cure the extension part of the adhesive layer.

According to the full lamination method of the display module, the adhesive layer is a UV-curable optically clear adhesive (OCA).

According to one embodiment of the full lamination method of the display module, the first deaerating treatment is performed under a condition that a temperature is controlled to be 30° C. to 40° C., a deaerating pressure is 50.3 MPa, and a deaerating time is 10 minutes.

Advantageous effects of the present invention: The present invention provides the display module and the full bonding method of the display module. The OCA is extended beyond the glass substrate, and UV curing is performed on a lateral side of the display module, so that the OCA extended out of the glass substrate is solidified to prevent impurities such as water/moisture from entering the inside of the display module. In addition, through two deaerating treatments, the present invention avoids occurrence of bubbles at a boundary between the visible region and the black matrix region of the cover plate of the blind hole product.

### BRIEF DESCRIPTION OF THE DRAWINGS

In order to more clearly illustrate the embodiments of the present disclosure or related art, figures which will be described in the embodiments are briefly introduced hereinafter. It is obvious that the drawings are merely for the purposes of illustrating some embodiments of the present disclosure, a person having ordinary skill in this field can obtain other figures according to these figures without an inventive work or paying the premise.

FIG. 1 is a schematic cross-sectional view illustrating a display module according to a first embodiment of the present invention;

FIG. 2 is a schematic planar view illustrating the display module according to the first embodiment of the present invention;

FIG. 3 is another schematic cross-sectional view illustrating the display panel according to the first embodiment of the present invention;

FIG. 4 is a schematic cross-sectional view illustrating the display panel having a blind hole according to the first embodiment of the present invention; and

FIG. 5 is a process flow diagram illustrating a full lamination method of the display panel according to a second embodiment of the present invention.

### DETAILED DESCRIPTION OF THE EMBODIMENTS

The following description is provided to illustrate specific embodiments of the present invention. Directional terms mentioned in the present disclosure, such as “upper”, “lower”, “front”, “rear”, “left”, “right”, “inside”, “outside”, “lateral”, are only illustrative with reference to the accompanying drawings. The directional terminology used is for illustrative purposes to ease understanding of the present disclosure. In the drawings, structurally similar elements are denoted by the same reference numerals.

The present invention is directed to solving problems with a conventional display module and a full lamination method thereof. The present invention can solve the problem that when a cover plate and a display panel are fully bonded, bubbles are easily generated at a boundary between a visible region and a black matrix region of the cover plate, and ambient water/moisture easily enters the display module.

### First Embodiment

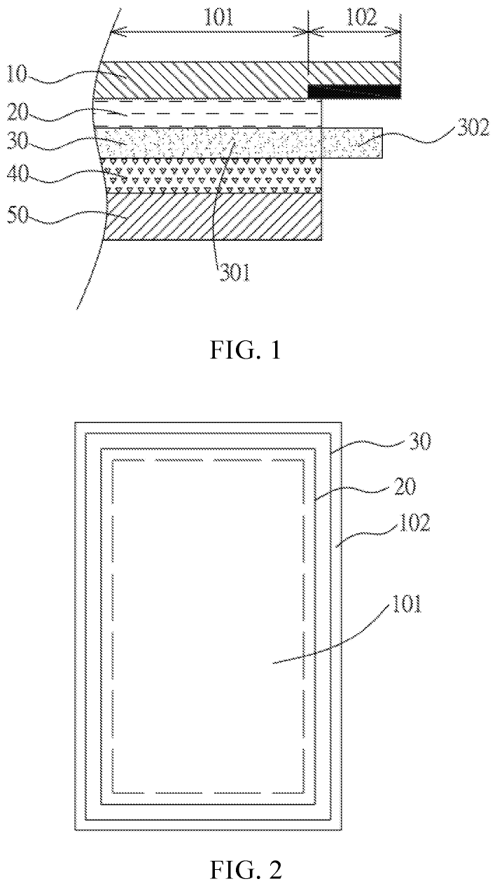

Please refer to FIG. 1 which is a schematic cross-sectional view illustrating a display module according to the first embodiment of the present invention. The display module comprises a cover plate 10, a glass substrate 20, a display panel 50, and an adhesive layer 30.

The cover plate 10 comprises a visible region 101 and a black matrix region 102 surrounding the visible region 101. The visible region 101 is used for displaying images, and the black matrix region 102 is an opaque region.

The glass substrate 20 is combined with the cover plate 10. A periphery of the glass substrate 20 overlaps the black matrix region 102. In other words, an outer edge of the glass substrate 20 is disposed in the black matrix region 102, and a touch sensing circuit is disposed on the glass substrate. It should be noted that, the outer edge is defined with respect to inner and outer sides of the display module.

The display panel 50 is disposed at one side of the glass substrate 20 away from the cover plate 10. The display panel 50 can be a liquid crystal display panel, or an organic light-emitting diode (OLED) display panel, and etc.; however, the present invention is not limited in this regard. The display panel 50 includes an array substrate, a color filter substrate, and a liquid crystal layer between the array substrate and the color filter substrate. Those are prior arts and will not be described herein for brevity.

The display module further comprises a polarizer 40. The polarizer 40 is disposed on one side of the display panel 50 adjacent to the cover plate 10. In regard to the liquid crystal display panel, there is another polarizer (not illustrated), and the another polarizer is disposed at an opposite side of the display panel. To be specific, the upper polarizer is disposed on one side of the color filter substrate away from the array substrate, and the lower polarizer is disposed on one side of the array substrate away from the color filter substrate.

When the cover plate 10 and the display panel 50 are fully bonded, an adhesive layer 30 needs to be disposed between the cover plate 10 and the display panel 50. To be specific, the adhesive layer 30 is disposed between the glass substrate 20 and the polarizer 40, and the adhesive layer 30 comprises a main part 301 and an extension part 302. The main part 301 is disposed corresponding to the visible region 101 and a boundary between the visible region 101 and the black matrix region 102. The extension part 302 is extended from the main part 301 to outside the display module. An orthographic projection of an outer edge of the extension part 302 projected onto the glass substrate 20 is located outside the glass substrate 20.

As shown in FIG. 2, the main part 301 is arranged corresponding to the display panel 50 and the glass substrate 20. An outer edge of the adhesive layer 30 is located outside an outer edge of the glass substrate 20 and an outer edge of the black matrix region 102.

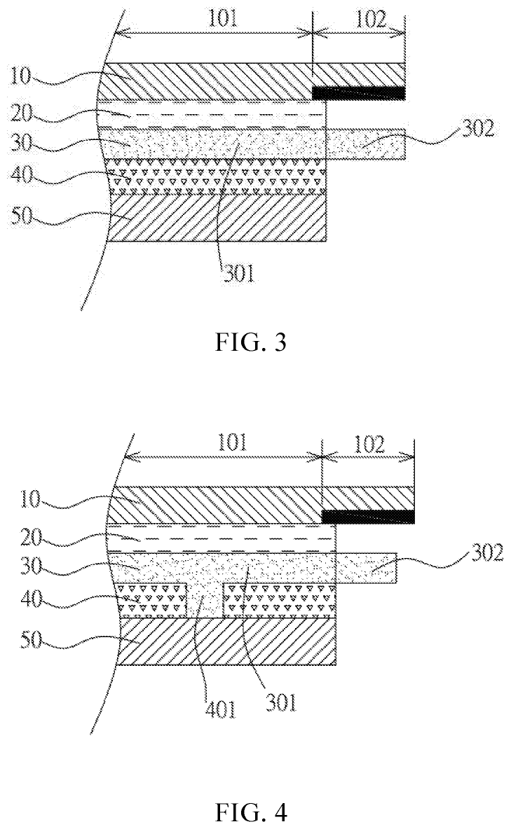

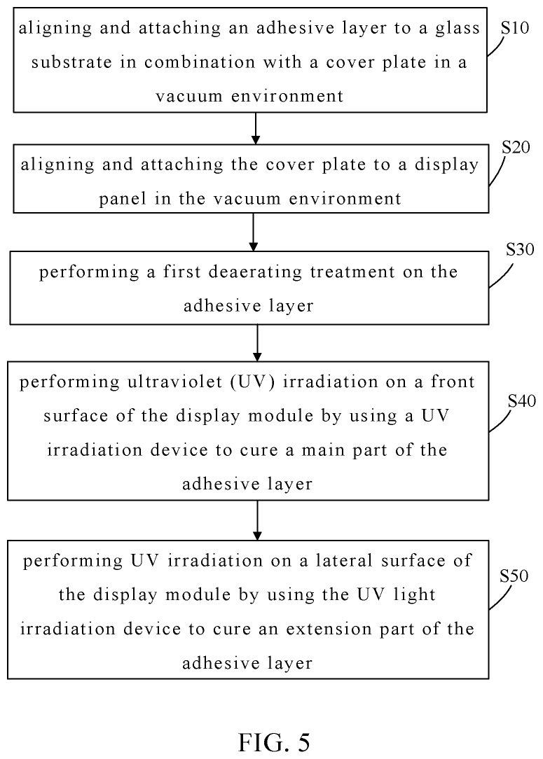

Further, as shown in FIG. 3, the orthographic projection of the outer edge of the extension part 302 projected onto the glass substrate 20 coincides with the outer edge of the black matrix region 102.

The adhesive layer 30 is an optically clear adhesive (OCA) which is an optically transparent double-sided adhesive. One side of the adhesive layer 30 is bonded to the glass substrate 20, and the other side is attached to the polarizer 40.

When the cover plate 10 and the display panel 50 are fully bonded, the adhesive layer 30 is usually subjected to ultraviolet (UV) light curing or an aging treatment, and the adhesive layer 30 generates a contraction stress during UV curing. Since the black matrix region 102 blocks UV light, the adhesive layer 30 in the black matrix region 102 cannot be irradiated by the UV light and cannot be completely cured, and the adhesive layer 30 arranged corresponding to the black matrix region 102 cannot generate contraction stress. As a result, the contraction stress is concentrated on an edge of the visible region 101, and a certain amount of bubbles appear in the adhesive layer 30 of the display module at positions corresponding to the edge of the visible region 101 under high temperature and high humidity conditions, which affects the quality of the display module. By using the extension design of the adhesive layer 30, the extension part 302 is UV-cured through a lateral side of the display module, so that the extension part 302 is solidified. Therefore, impurities such as water/moisture are prevented from entering the inside of the display module, the display module is protected from foreign matters, and bubbles are also prevented from occurring at edges.

Furthermore, as shown in FIG. 4, the display module may has a blind hole design. That is, a blind hole is formed in the polarizer 40. A camera, a fingerprint identification device, or other photosensitive element may be placed at a position corresponding to the blind hole 401 at a bottom of the display panel 50. Through the blind hole 401, external light can be transmitted to the photosensitive element. The blind hole 401 is arranged corresponding to the visible region 101. Since there is a level difference between the blind hole 401 and a normal surface, an ultra-soft OCA is used to be the adhesive layer 30 in the present embodiment. Specifically, the OCA optical is an UV-OCA. The adhesive layer 30 is made of soft OCA, so the adhesive layer 30 can effectively cover the level difference at the blind hole 401, and the adhesive layer 30 is completely adhered to a side wall and a bottom of the blind hole 401. After the adhesive layer 30 inside and outside the blind hole 401 of the display module undergoes deaeration, remaining bubbles can be uniformly spread to an entire in-plane area.

Moreover, the display module can be a touch display module. In other words, a touch sensing circuit is disposed on the glass substrate 20.

### Second Embodiment

The present invention provides a full lamination method of a display module, comprising following steps:

Step S10: aligning and attaching an adhesive layer 30 to a glass substrate 20 in combination with a cover plate 10 in a vacuum environment.

Specifically, the cover plate 10 comprises a visible region 101 and a black matrix region 102. The glass substrate 20 combines the cover plate 10 and a periphery of the glass substrate 20 overlaps the black matrix region 102 of the cover plate 10. The adhesive layer 30 is an ultraviolet-curable optically clear adhesive (UV-OCA).

Step S20: aligning and attaching the cover plate 10 to a display panel 50 in the vacuum environment.

Step S30: performing a first deaerating treatment on the adhesive layer 30.

Specifically, in-plane deaeration is performed under low temperatures and low pressures, wherein the first deaerating treatment are performed under a condition that a temperature is controlled to be 30° C. to 40° C., a deaerating pressure is 50.3 MPa, and a deaerating time is 10 minutes.

Step S40: performing ultraviolet (UV) irradiation on a front surface of the display module by using a UV irradiation device to cure a main part 301 of the adhesive layer 30.

Specifically, after the first deaerating treatment is performed, the blind hole 401 in the polarizer is shielded from light by using a light-shielding cover to prevent UV light from being irradiated into the blind hole 401 to cure the main part 301 of the adhesive layer 30.

step S50: performing UV irradiation on a lateral surface of the display module by using the UV light irradiation device to cure an extension part 302 of the adhesive layer 30.

It should be noted that, in the present invention, the display module adopts a blind-hole design as an example. When the first deaerating treatment is performed on the display module with the blind-hole design after adhering of the adhesive layer 30, requirements and conditions for performing deaeration inside the blind hole 401 and in an in-plane area are not the same. As a result, it is unable to remove all the bubbles from the display module by only one deaerating treatment. Therefore, two deaerating treatments are performed in the full lamination method of the display module of the present invention.

After step S40, a second deaerating treatment is performed on the adhesive layer 30 inside the blind hole 401 under high temperatures and high pressures. The second deaerating treatment is performed under a condition that the temperature is controlled to be 60° C. to 70° C., the deaerating pressure is 0.5 MPa, and a deaerating time is 30 minutes. Since the UV-OCA optical is relatively soft, after the second deaerating treatment, the remaining in-plane bubbles in the in-plane area can be uniformly spread throughout the entire in-plane area.

### ADVANTAGES OF THE PRESENT INVENTION

The present invention provides the display module and the full lamination method of the display module. The OCA is extended beyond the glass substrate, and UV irradiation is performed on a lateral surface of the display module to solidify the portion of the OCA extended out of the glass substrate, thereby preventing impurities such as water/moisture from entering the inside of the display module. In addition, through two deaerating treatments, the present invention avoids occurrence of bubbles at the boundary between the visible region and the black matrix region of the cover plate of the blind-hole product.

Although the present disclosure is disclosed above in conjunction with preferable embodiments, the above embodiments are not intended to limit the present disclosure. Those skilled in the art can make various modifications without departing from the spirit and scope of the present disclosure. The protection scope of the present invention is defined by the appended claims.

What is claimed is:

1. A display module, comprising:
a cover plate comprising a visible region and a black matrix region surrounding the visible region;
a glass substrate combined with the cover plate, wherein an outer edge of the glass substrate is disposed corresponding to the black matrix region, and a touch sensing circuit is disposed on the glass substrate;
a display panel disposed at one side of the glass substrate away from the cover plate; and
an adhesive layer disposed between the glass substrate and the display panel, the adhesive layer comprising a main part and an extension part, wherein the extension part is disposed at a periphery of the main part, wherein an orthographic projection of an outer edge of the extension part, which is projected onto the glass substrate, is located outside the glass substrate.

2. The display module according to claim 1, wherein the orthographic projection of the outer edge of the extension part, which is projected onto the glass substrate, coincides with an outer edge of the black matrix region.

3. The display module according to claim 1, further comprising a polarizer, wherein the polarizer is disposed on one side of the display panel adjacent to the cover plate, a blind hole is defined in the polarizer, the blind hole is disposed corresponding to the visible region of the cover plate, and the adhesive layer is snugly attached to a sidewall and a bottom of the blind hole.

4. The display module according to claim 3, wherein a camera and a fingerprint identification device are disposed in a bottom portion of the display panel and arranged corresponding to the blind hole.

5. The display module according to claim 1, wherein the adhesive layer is made of an ultraviolet-curable optically clear adhesive (OCA).

6. The display module according to claim 1, wherein the display panel is a liquid crystal display (LCD) panel or an organic light-emitting diode (OLED) display panel.

7. The display module according to claim 1, wherein the display module is a touch display module.

8. A display module, comprising:
a cover plate comprising a visible region and a black matrix region surrounding the visible region;
a glass substrate combined with the cover plate, wherein an outer edge of the glass substrate is disposed corresponding to the black matrix region;
a display panel disposed on one side of the glass substrate away from the cover plate; and
an adhesive layer disposed between the glass substrate and the display panel, the adhesive layer comprising a main part and an extension part, wherein the extension part is disposed at a periphery of the main part, wherein an orthogonal projection of the outer edge of the extension part, which is projected onto the glass substrate, is located at an outer edge of the glass substrate.

9. The display module according to claim 8, wherein an orthographic projection of the outer edge of the extension part, which is projected onto the glass substrate, coincides with an outer edge of the black matrix region.

10. The display module according to claim 8, further comprising a polarizer, wherein the polarizer is disposed on one side of the display panel adjacent to the cover plate, a blind hole is defined in the polarizer, the blind hole is arranged corresponding to the visible region of the cover plate, and the adhesive layer is snugly attached to a sidewall and a bottom of the blind hole.

11. The display module according to claim 10, wherein a camera and a fingerprint identification device are disposed in a bottom portion of the display panel and arranged corresponding to the blind hole.

12. The display module according to claim 8, wherein the adhesive layer is an ultraviolet (UV)-curable optically clear adhesive (OCA).

13. The display module according to claim 8, wherein the display panel is a liquid crystal display (LCD) panel or an organic light-emitting diode (OLED) display panel.

14. The display module according to claim 8, wherein the display module is a touch display module.

15. A full lamination method of a display module, comprising following steps:
step S10: aligning and attaching an adhesive layer to a glass substrate in combination with a cover plate in a vacuum environment;
step S20: aligning and attaching the cover plate to a display panel in the vacuum environment;
step S30: performing a first deaerating treatment on the adhesive layer;
step S40: performing ultraviolet (UV) irradiation on a front surface of the display module by using a UV irradiation device to cure a main part of the adhesive layer; and
step S50: performing UV irradiation on a lateral surface of the display module by using the UV light irradiation device to cure an extension part of the adhesive layer.

16. The full lamination method of the display module according to claim 15, wherein in step S40, after performing the first deaerating treatment on the adhesive layer, a blind hole defined in a polarizer is shielded by a light shield to cure the main part of the adhesive layer.

17. The full lamination method of the display module according to claim 15, wherein step S50 further comprises performing a second deaerating treatment, and then performing UV irradiation on the lateral surface of the display module by using the UV irradiation device to cure the extension part of the adhesive layer.

18. The full lamination method of the display module according to claim 15, wherein the adhesive layer is a UV-curable optically clear adhesive (OCA).

19. The full lamination method of the display module according to claim 15, wherein the first deaerating treatment is performed under a condition that a temperature is controlled to be 30° C. to 40° C., a deaerating pressure is 50.3 MPa, and a deaerating time is 10 minutes.
